(19) United States
(12) Patent Application Publication
(10) Pub. No.: US 2011/0229719 A1
(43) Pub. Date: Sep. 22, 2011

(54) MANUFACTURING METHOD FOR CRYSTAL, MANUFACTURING APPARATUS FOR CRYSTAL, AND STACKED FILM

(75) Inventors: Taro NISHIGUCHI, Itami-shi (JP); Shin Harada, Osaka-shi (JP)

(73) Assignee: SUMITOMO ELECTRIC INDUSTRIES, LTD., Osaka-shi (JP)

(21) Appl. No.: 13/048,064

(22) Filed: Mar. 15, 2011

(30) Foreign Application Priority Data
Mar. 16, 2010 (JP) 2010-059144

(51) Int. Cl. C30B 23/02; B32B 9/04; B32B 15/04

(52) U.S. Cl. 428/408; 117/106; 428/457; 428/698; 118/728

(57) ABSTRACT

A manufacturing method for a crystal, a manufacturing apparatus for a crystal, and a stacked film capable of growing a high-quality crystal are provided. The manufacturing method for a crystal includes the steps of: preparing a seed crystal having a frontside surface and a backside surface opposite to the frontside surface; forming at least one film selected from the group consisting of a hard carbon film, a diamond film, a tantalum film, and a tantalum carbide film on the backside surface of the seed crystal; and growing the crystal on the frontside surface of the seed crystal.

### BACKGROUND OF THE INVENTION

1. Field of the Invention

The present invention relates to a manufacturing method for a crystal, a manufacturing apparatus for a crystal, and a stacked film, and in particular to a manufacturing method for a crystal, a manufacturing apparatus for a crystal, and a stacked film using a seed crystal.

2. Description of the Background Art

In recent years, silicon carbide (SiC) substrates have been adopted as semiconductor substrates for use in manufacturing semiconductor devices. SiC has a band gap larger than that of silicon (Si), which has been used more commonly in the field of semiconductor. Hence, a semiconductor device employing SiC advantageously has a large reverse breakdown voltage, low on-resistance, or has properties less likely to decrease in a high temperature environment.

A SiC crystal is manufactured using a sublimation method that allows the SiC crystal to grow on a surface of a seed crystal. As a method of growing a crystal by the sublimation method, for example, the following two methods have been proposed. Firstly, according to Japanese Patent Laying-Open No. 2001-139394 (Patent Document 1), when a single crystal is grown, a carbon composite structure having graphite fine particles and non-graphitizable carbon is formed in an interface between a seed crystal and a seed crystal pedestal. Patent Document 1 describes that, since carbon (C) is thereby uniformly formed all over an attachment surface using heat-resistant fine particles uniformly dispersed in the attachment surface as cores, and covers an attachment surface of the seed crystal, it is possible to prevent occurrence of recrystallization in the attachment surface of the seed crystal to be attached to the pedestal during growth of the single crystal, and it is also possible to prevent etching which may occur at a central portion of the seed crystal in an early stage of the growth.

Secondly, according to Japanese Patent Laying-Open No. 2003-226600 (Patent Document 2), a seed crystal having a backside surface coated with an organic thin film with a thickness of 0.5 to 5 μm is mechanically mounted to a graphite crucible lid. Patent Document 2 describes that, since the organic thin film can prevent sublimation of Si atoms from the backside surface of the seed crystal, generation of voids in a crystal is suppressed.

### SUMMARY OF THE INVENTION

In the technique of Patent Document 1 described above, there has been a possibility that strength of fixing between the seed crystal and the pedestal may be insufficient, depending on the material for the seed crystal. Particularly, if the temperature between the seed crystal and the pedestal is set to a high temperature as in the case where, for example, a SiC crystal is grown, the strength of fixing described above has been likely to be reduced. Therefore, there has been a possibility that a gap may occur between the seed crystal and the pedestal, and thus the backside surface (surface connected with the pedestal) of the seed crystal may sublime. Hence, there has been a possibility that the quality of the obtained crystal may be reduced.

As to the technique of Patent Document 2 described above, the present inventor has found as a result of examination that air bubbles may be generated in the organic thin film when the backside surface of the seed crystal is coated with the organic thin film. That is, the present inventor has found that air bubbles are also generated between the seed crystal and the organic thin film. Thus, there has been a possibility that a gap may occur between the seed crystal and the organic thin film. There has been a possibility that the backside surface of the seed crystal may sublime from the gap, causing a reduction in the quality of an obtained crystal as in Patent Document 1 described above.

The present invention has been made in view of the aforementioned problem, and one object of the present invention is to provide a manufacturing method for a crystal, a manufacturing apparatus for a crystal, and a stacked film capable of growing a high-quality crystal.

The present inventor paid attention to forming a film to suppress sublimation of the backside surface of a seed crystal. As a result of earnest study on a material for the film for suppressing sublimation of the backside surface of the seed crystal, the present inventor has completed the present invention.

Specifically, a manufacturing method for a crystal of the present invention includes the steps of: preparing a seed crystal having a frontside surface and a backside surface opposite to the frontside surface; forming at least one film selected from the group consisting of a hard carbon film, a diamond film, a tantalum (Ta) film, and a tantalum carbide (TaC) film on the backside surface of the seed crystal; and growing the crystal on the frontside surface of the seed crystal.

As a result of earnest study, the present inventor has found that a gap (void) is less likely to occur in a hard carbon film, a diamond film, a Ta film, and a TaC film during formation. The present inventor has also found that these films are less likely to be thermally decomposed when heat is applied thereto. Thus, the manufacturing method for the crystal of the present invention can suppress occurrence of a gap between the seed crystal and the film when the film is formed, and also suppress decomposition of the film when the crystal is grown. Hence, when the crystal is grown, the backside surface of the seed crystal is coated with the film, and thereby sublimation of the backside surface can be suppressed. Consequently, the quality of the crystal grown on the seed crystal can be improved.

Preferably, in the manufacturing method for the crystal described above, in the step of forming the film, a diamond-like carbon (DLC) film is formed. Since DLC is chemically stable, it can further suppress sublimation of the backside surface of the seed crystal in an atmosphere where the crystal is manufactured.

Preferably, in the manufacturing method for the crystal described above, in the step of forming the film, the hard carbon film is formed by plasma polymerization processing. Thereby, the hard carbon film can be easily formed.

Preferably, in the manufacturing method for the crystal described above, in the step of forming the film, the diamond film as a polycrystal is formed. Even if the seed crystal and the diamond film are made of different materials, the diamond film as a polycrystal can be easily formed on the backside surface of the seed crystal.

Preferably, in the manufacturing method for the crystal described above, in the step of forming the film, the diamond film is formed by a microwave plasma CVD method. Thereby, the diamond film can be easily formed.

Preferably, the manufacturing method for the crystal described above further includes the step of polishing the backside surface of the seed crystal prior to the step of forming the film.

Thereby, a damaged region in the backside surface of the seed crystal can be removed. This can further suppress occurrence of a gap between the backside surface of the seed crystal and the film.

Preferably, the manufacturing method for the crystal described above further includes the step of connecting the film and a pedestal using an adhesive.

As a result of earnest study, the present inventor has found that the quality of the grown crystal is more influenced by a gap that occurs in an interface between the film and the seed crystal, rather than a gap that occurs in an interface between the pedestal and the adhesive, and a gap that occurs in an interface between the adhesive and the film. Since occurrence of a gap in the interface between the film and the seed crystal can be suppressed in the present invention, a crystal with improved quality can be manufactured by mounting the seed crystal having the film formed thereon on the pedestal by connecting the film and the pedestal using the adhesive.

Preferably, the manufacturing method for the crystal described above further includes the step of polishing a region in the pedestal to be connected with the film prior to the step of connecting the film and the pedestal. This can suppress occurrence of a gap between the pedestal and the adhesive.

Preferably, in the manufacturing method for the crystal described above, in the step of growing, a SiC crystal is grown. Thereby, a high quality SiC crystal can be manufactured.

A stacked film of the present invention includes a film, a seed crystal, and a crystal. The film is at least one film selected from the group consisting of a hard carbon film, a diamond film, a tantalum film, and a tantalum carbide film. The seed crystal is formed on the film. The crystal is formed on the seed crystal.

The stacked film of the present invention includes the film in which a gap is less likely to occur during film formation and which is less likely to be thermally decomposed when heat is applied thereto. Thus, the crystal formed on a side of the seed crystal opposite to the film is manufactured with sublimation of the seed crystal being suppressed. Therefore, a stacked film including a high-quality crystal can be realized. If a semiconductor device is fabricated using this high-quality crystal, the quality of the semiconductor device can also be improved.

A manufacturing apparatus for a crystal of the present invention includes a source material holding unit for placing a source material therein, and a pedestal holding a seed crystal at a position facing the source material placed inside the source material holding unit. The pedestal is connected with at least one film selected from the group consisting of a hard carbon film, a diamond film, a tantalum film, and a tantalum carbide film formed on a surface of the seed crystal to be connected with the pedestal.

When the manufacturing apparatus for the crystal of the present invention is used, the seed crystal with the film in which a gap is less likely to occur during film formation and which is less likely to be thermally decomposed when heat is applied thereto is used together. Thus, when the crystal is manufactured, the crystal can be manufactured with sublimation of the backside surface of the seed crystal being suppressed. Therefore, a crystal with improved quality can be manufactured on the seed crystal.

As described above, with the manufacturing method for a crystal, the manufacturing apparatus for a crystal, and the stacked film of the present invention, a high-quality crystal can be grown.

The foregoing and other objects, features, aspects and advantages of the present invention will become apparent from the following detailed description of the present invention when taken in conjunction with the accompanying drawings.

### BRIEF DESCRIPTION OF THE DRAWINGS

FIG. 1 is a cross sectional view schematically showing a stacked film according to an embodiment of the present invention.

FIG. 2 is a cross sectional view schematically showing a manufacturing apparatus for a crystal according to the embodiment of the present invention.

FIG. 3 is a cross sectional view schematically showing each step of a manufacturing method for the crystal according to the embodiment of the present invention.

FIG. 4 is a cross sectional view schematically showing each step of the manufacturing method for the crystal according to the embodiment of the present invention.

FIG. 5 is a cross sectional view schematically showing a state where a seed crystal is mounted on a pedestal in comparative example 1.

FIG. 6 is a cross sectional view schematically showing a state where a seed crystal is mounted on a pedestal in comparative example 2.

### DESCRIPTION OF THE PREFERRED EMBODIMENTS

Hereinafter, an embodiment of the present invention will be described with reference to the drawings. It is to be noted that, in the drawings below, identical or corresponding parts will be designated by the same reference numerals, and the description thereof will not be repeated. Further, in the present specification, an individual plane will be indicated by ( ) and a group plane will be indicated by { }. In addition, although a negative index is crystallographically supposed to be indicated by placing “-” (a bar) above a numeral, it will be indicated in the present specification by placing a minus sign before a numeral.

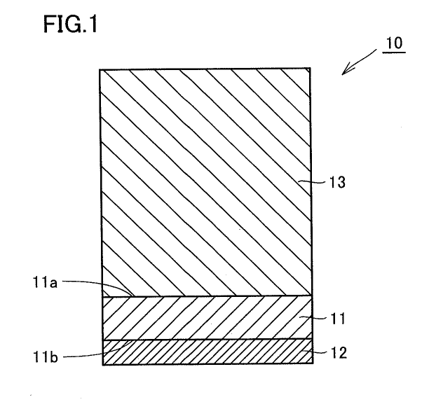

FIG. 1 is a cross sectional view schematically showing a stacked film 10 according to an embodiment of the present invention. Firstly, stacked film 10 according to one embodiment of the present invention will be described with reference to FIG. 1. Stacked film 10 includes a seed crystal 11, a film 12, and a crystal 13. Seed crystal 11 is formed on film 12. Crystal 13 is formed on seed crystal 11.

Film 12 is at least one film selected from the group consisting of a hard carbon film, a diamond film, a Ta film, and a TaC film. Film 12 may include two or more layers.

The thickness of film 12 (dimension in a longitudinal direction in the drawing) is not particularly limited, and is preferably, for example, not less than 1 μm and not more than 100 μm.

A hard carbon film refers to a ultra hard carbon film commonly called as “i carbon”, which has many similarities to diamond in terms of physical properties, and has a black color. The hardness of the hard carbon film is, for example, not less than 3000 HV. Examples of the hard carbon film include DLC.

If film 12 includes a hard carbon film, the hard carbon film is preferably a diamond-like carbon (DLC) film. The DLC film is an amorphous hard carbon film mainly composed of carbon (C) and hydrogen (H). The DLC film is chemically stable, and has high heat conductivity, excellent wear resistance, and a low friction coefficient.

If film 12 includes a diamond film, the diamond film may be a polycrystalline diamond film.

Seed crystal 11 has a frontside surface 11a and a backside surface 11b opposite to frontside surface 11a. Backside surface 11b is in contact with film 12. Frontside surface 11a is in contact with crystal 13. An off angle of frontside surface 11a, that is, a tilt of the plane orientation of seed crystal 11 from the {0001} plane, is preferably not more than 15°, and more preferably not more than 5°.

The planar shape of seed crystal 11 is, for example, a circle, and the diameter thereof is preferably not less than 25 mm, and more preferably not less than 100 mm. In addition, the thickness of seed crystal 11 (dimension in the longitudinal direction in the drawing) is preferably not less than 0.5 mm and not more than 10 mm.

Preferably, seed crystal 11 has the same composition as crystal 13. In the present embodiment, seed crystal 11 is a SiC crystal. If seed crystal 11 is a SiC crystal, the polytype (crystalline polymorph) of the SiC crystal is preferably 4H—SiC, although it is not particularly limited.

Crystal 13 has high quality, which means that, for example, crystal 13 has a micropipe density of not more than 1 cm⁻². The micropipe density is a value obtained for example by soaking crystal 13 in a potassium hydroxide (KOH) melt kept at 500° C. for 1 to 10 minutes, and performing a measurement on an etched surface thereof using a Nomarski differential interference microscope.

Preferably, crystal 13 is a SiC crystal. In this case, the polytype of the SiC crystal is preferably 4H—SiC, although it is not particularly limited. Further, preferably, crystal 13 is a single crystal.

An interface between frontside surface 11a of seed crystal 11 and crystal 13 has a reduced gap, and has a void density of, for example, less than 10 cm⁻². The void density is a value measured for example by observing a cross section of the interface between frontside surface 11a of seed crystal 11 and crystal 13 with a microscope.

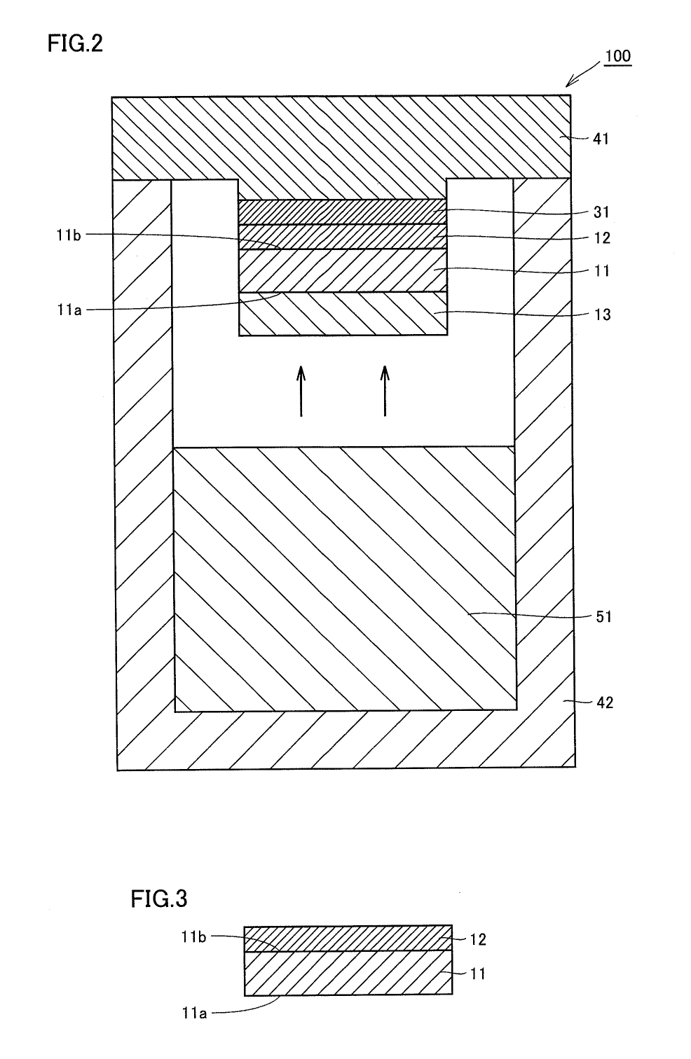

FIG. 2 is a cross sectional view schematically showing a manufacturing apparatus 100 for crystal 13 according to the embodiment of the present invention. Next, manufacturing apparatus 100 for the crystal according to one embodiment of the present invention will be described. Manufacturing apparatus 100 grows the crystal by the sublimation method.

Manufacturing apparatus 100 includes a pedestal 41 and a source material holding unit 42. In the present embodiment, pedestal 41 functions as a lid for source material holding unit 42. Pedestal 41 and source material holding unit 42 constitute a crucible.

Source material holding unit 42 holds a source material 51 placed therein. Pedestal 41 holds seed crystal 11 at a position facing source material 51 placed inside source material holding unit 42. Pedestal 41 and source material holding unit 42 are made of, for example, graphite.

Pedestal 41 is connected with at least one film selected from the group consisting of a hard carbon film, a diamond film, a tantalum film, and a tantalum carbide film formed on backside surface 11b of seed crystal 11.

Although manufacturing apparatus 100 may include various elements other than those described above, these elements will not be shown and described for convenience of explanation.

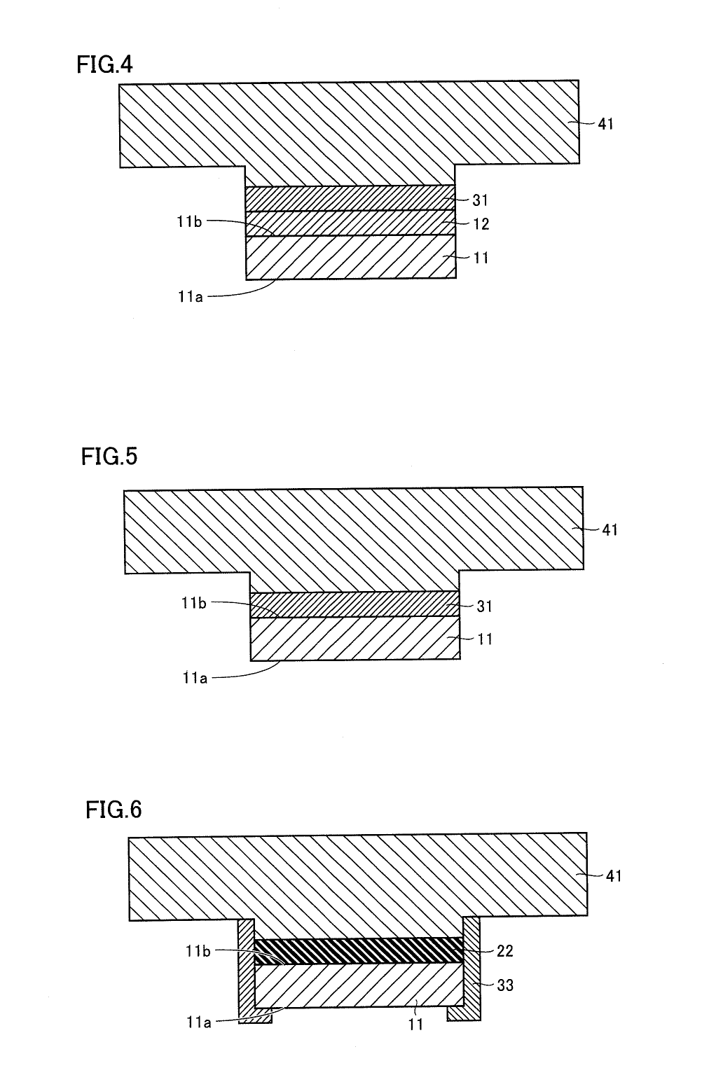

FIGS. 3 and 4 are cross sectional views schematically showing each step of a manufacturing method for crystal 13 according to the embodiment of the present invention. Next, the manufacturing method for the crystal according to the present embodiment will be described with reference to FIGS. 1 to 4.

Firstly, as shown in FIG. 3, seed crystal 11 is prepared. Seed crystal 11 has frontside surface 11a as a surface on which the crystal will grow, and backside surface 11b as a surface to be mounted on the pedestal. For example, seed crystal 11 is a SiC substrate. Seed crystal 11 has a thickness of, for example, not less than 0.5 mm and not more than 10 mm. In addition, the planar shape of seed crystal 11 is, for example, a circle, and the diameter thereof is preferably not less than 25 mm, and more preferably not less than 100 mm. Further, the tilt of the plane orientation of the seed crystal from the {0001} plane, that is, the off angle, is preferably not more than 15°, and more preferably not more than 5°.

Subsequently, backside surface 11b is polished to improve flatness of backside surface 11b. For the polishing, for example, diamond slurry can be used. The slurry contains diamond particles with a particle size of, for example, not less than 5 μm and not more than 100 μm, more preferably not less than 10 μm and not more than 20 μm.

Next, as shown in FIG. 3, at least one film 12 selected from the group consisting of a hard carbon film, a diamond film, a Ta film, and a TaC film is formed on backside surface 11b of seed crystal 11. Film 12 in which two or more films are stacked may be formed. Preferably, film 12 is formed to be in contact with backside surface 11b of seed crystal 11.

If a hard carbon film is formed as film 12 in this step, the formed film is chemically stable and has high heat conductivity. It is particularly preferable to form a DLC film as the hard carbon film. Further, it is preferable to form the hard carbon film by plasma polymerization processing in a gas atmosphere containing hydrocarbon. The plasma polymerization processing is performed, for example, as described below.

A plasma polymerization apparatus used for the plasma polymerization processing is a parallel plate type apparatus in which high-frequency applying electrodes, that is, a cathode electrode and an anode electrode, are placed in parallel. As the cathode electrode, a metal member such as a stainless plate is provided. As the anode electrode, a metal member such as a stainless plate is provided. In addition, seed crystal 11 is provided inside the apparatus. Thereafter, hydrocarbon gas, a mixed gas containing hydrocarbon gas and hydrogen or argon, or the like is introduced from a gas inlet. Here, another rare gas such as helium can be used instead of argon. The pressure inside the apparatus is kept at, for example, not more than 13 Pa, and high-frequency electric power with a frequency of, for example, 13.56 MHz is applied to generate plasma. On this occasion, the high-frequency electric power ranges, for example, from several tens of watts to several hundred watts. Thereby, a hard carbon film such as a DLC film with a thickness of, for example, about 1 μm can be formed.

Further, if a diamond film is formed as film 12 in this step, the formed film is dense, and has high strength and higher heat conductivity. In this case, it is preferable to form the diamond film by a microwave plasma CVD method. The microwave plasma CVD method is performed, for example, as described below.

Firstly, seed crystal 11 is provided in a microwave plasma CVD apparatus. Thereafter, for example, 2 sccm methane, 90 sccm hydrogen, and 10 sccm nitrogen diluted to 1000 ppm in hydrogen are introduced into the apparatus. A diamond film is formed with a temperature of a base material being set, for example, to 950° C. and a pressure being set to 13.3 kPa. Time taken for forming the film is, for example, 10 hours. Thereby, a diamond film with a thickness of, for example, about 0.1 mm can be formed. In the present embodiment, since the diamond film is formed on a crystal of a different type, the formed diamond film is a polycrystal.

If at least one of a Ta film and a TaC film is included as film 12 in this step, the film has a high melting point and high strength. In this case, film 12 is formed on backside surface 11b of seed crystal 11, for example by a sputtering method.

Subsequently, as shown in FIG. 4, pedestal 41 having a mounting surface on which seed crystal 11 is to be mounted is prepared. Preferably, the mounting surface includes a surface made of carbon. For example, pedestal 41 is formed of graphite. Preferably, the mounting surface (region in pedestal 41 to be connected with film 12) is polished to improve flatness of the mounting surface.

Next, as shown in FIG. 4, film 12 and pedestal 41 are connected using an adhesive 31. The connection is performed, for example, as described below.

Firstly, film 12 and pedestal 41 are brought into contact with each other, with adhesive 31 interposed therebetween. Preferably, the contact is performed such that the both press against each other at a temperature of not less than 50° C. and not more than 120° C., and under a pressure of not less than 0.01 Pa and not more than 1 MPa. Further, adhesive 31 is applied so as not to spread out of a region sandwiched between seed crystal 11 and pedestal 41, which can suppress an adverse effect of adhesive 31 in the step of growing the crystal using seed crystal 11 described later.

Preferably, adhesive 31 includes a resin which will become non-graphitizable carbon by being heated and carbonized, heat-resistant fine particles, and a solvent. More preferably, adhesive 31 further includes a carbohydrate.

The resin which will become non-graphitizable carbon is, for example, a novolak resin, a phenol resin, or a furfuryl alcohol resin.

The heat-resistant fine particles have a function of uniformly distributing the non-graphitizable carbon described above in a fixing layer formed by heating adhesive 31 to a high temperature, and thereby increasing the filling rate of the fixing layer. As a material for the heat-resistant fine particles, a heat-resistant material such as carbon including graphite, SiC, boron nitride (BN), and aluminum nitride (AlN) can be used, and graphite fine particles are preferably used. In addition, a high melting point metal, or a compound such as a carbide or a nitride thereof can also be used as a material other than those described above. As the high melting point metal, for example, tungsten (W), Ta, molybdenum (Mo), titanium (Ti), zirconium (Zr), or hafnium (Hf) can be used. The heat-resistant fine particles have a particle size of, for example, 0.1 to 10 μm.

As the carbohydrate, a saccharide or a derivative thereof can be used. The saccharide may be a monosaccharide such as glucose, or a polysaccharide such as cellulose.

As the solvent, a solvent that can dissolve and disperse the resin and the carbohydrate described above is selected as appropriate. Further, the solvent is not limited to a solvent composed of a single type of liquid, and may be a mixed liquid containing plural types of liquids. For example, a solvent including alcohol for dissolving the carbohydrate and cellosolve acetate for dissolving the resin can be used.

The ratio among the resin, the carbohydrate, the heat-resistant fine particles, and the solvent in adhesive 31 is selected as appropriate to obtain suitable adhesion and fixing strength of seed crystal 11. In addition, the components of adhesive 31 may include a component other than those described above, and may include, for example, an additive such as a surfactant, a stabilizer, and the like. Further, the application amount of adhesive 31 is preferably not less than 10 mg/cm² and not more than 100 mg/cm². Furthermore, the thickness of adhesive 31 is preferably not more than 100 μm, and more preferably not more than 50 μm.

Thereafter, preferably, adhesive 31 is prebaked. The prebaking is performed at a temperature of, for example, not less than 80° C., and preferably not less than 150° C.

Further, adhesive 31 is heated. As a result of the heating, adhesive 31 is hardened between film 12 and pedestal 41, and formed as a fixing layer. Thereby, seed crystal 11 is fixed to pedestal 41.

Preferably, the heating described above is performed at a temperature of not less than 800° C. and not more than 1800° C., for a time period of not less than one hour and not more than 10 hours, under a pressure of not less than 0.13 kPa and not more than the atmospheric pressure, and in an inactive gas atmosphere. As an inactive gas, for example, helium, argon, or nitrogen gas is used.

Next, as shown in FIG. 2, source material 51 is placed inside source material holding unit 42. If the crystal to be grown is SiC, for example, SiC powder is placed in source material holding unit 42. Then, pedestal 41 is mounted on source material holding unit 42 such that seed crystal 11 faces the inside of source material holding unit 42. It is to be noted that pedestal 41 may function as a lid for source material holding unit 42 as shown in FIG. 2.

Subsequently, crystal 13 is grown on seed crystal 11. In the case where a SiC crystal is manufactured as crystal 13 using a SiC substrate as seed crystal 11, the sublimation method (sublimation-recrystallization method) can be used as a forming method therefor. Specifically, crystal 13 can be grown by subliming source material 51 as indicated by arrows in the drawing, and depositing a sublimate on seed crystal 11. The temperature in the sublimation method is set, for example, to not less than 2100° C. and not more than 2500° C. Further, the pressure in the sublimation method is preferably set, for example, to not less than 1.3 kPa and not more than the atmospheric pressure, and more preferably set to not more than 13 kPa to increase a growth rate.

By performing the steps described above, stacked film 10 including film 12, seed crystal 11 formed thereon, and crystal 13 formed thereon as shown in FIG. 1 can be manufactured.

It is to be noted that the crystal may be manufactured by removing seed crystal 11 and film 12 from manufactured stacked film 10. Further, a substrate such as a SiC substrate may be manufactured from crystal 13 of stacked film 10. Such a substrate is obtained, for example, by slicing crystal 13.

Further, although a crystal formed of SiC (SiC crystal) has been described as seed crystal 11 in the present embodiment, a crystal formed of another material may be used. As a material therefor, for example, gallium nitride (GaN), zinc selenide (ZnSe), zinc sulfide (ZnS), cadmium sulfide (CdS), cadmium telluride (CdTe), aluminum nitride (AlN), boron nitride (BN), or the like can be used.

Subsequently, effects of the manufacturing method and manufacturing apparatus 100 for the crystal, and stacked film 10 according to the present embodiment will be described in comparison to comparative example 1 shown in FIG. 5 and comparative example 2 shown in FIG. 6. FIGS. 5 and 6 are cross sectional views schematically showing states where seed crystal 11 is mounted on pedestal 41 in comparative examples 1 and 2.

As shown in FIG. 5, in comparative example 1, seed crystal 11 and pedestal 41 are bonded using adhesive 31, without film 12 shown in FIG. 4 interposed therebetween. In comparative example 1, strength of fixing between seed crystal 11 and pedestal 41 may be insufficient, depending on the material for seed crystal 11. Particularly, if the temperature between seed crystal 11 and pedestal 41 is set to a high temperature as in the case where, for example, a SiC single crystal is grown by the sublimation method, the strength of fixing described above is likely to be reduced. For example, an adhesion strength obtained by adhesive 31 formed by hardening a carbon-based adhesive is likely to be reduced under a temperature of about 2000° C. generally used to grow SiC. Further, in this case, while seed crystal 11 is often formed of SiC, and pedestal 41 is often formed of graphite, it is difficult to firmly fix the both using adhesive 31 due to material properties of the both. For example, although a fixing layer formed by hardening a carbon-based adhesive can bond carbon materials (graphites) with high strength, the fixing layer cannot bond a carbon material and SiC with a comparable strength. As a result, there occurs a gap between seed crystal 11 and pedestal 41. That is, at least a portion of backside surface 11b of seed crystal 11 is exposed to an atmosphere.

In comparative example 2 shown in FIG. 6, seed crystal 11 provided with an organic thin film 22 with a thickness of 0.5 to 5 μm is fixed to pedestal 41 using a mechanical fixture 33. In comparative example 2, air bubbles may be generated in organic thin film 22 when backside surface 11b of seed crystal 11 is coated with organic thin film 22. That is, air bubbles are also generated between seed crystal 11 and organic thin film 22. Thus, there occurs a gap between seed crystal 11 and organic thin film 22. That is, at least a portion of backside surface 11b of seed crystal 11 is exposed to the atmosphere.

Further, in comparative example 2, seed crystal 11 and pedestal 41 are connected using fixture 33. Thus, there may occur a gap between seed crystal 11 and pedestal 41, specifically in an interface between organic thin film 22 and pedestal 41, due to a difference in thermal expansion coefficient between the material for seed crystal 11 and the material for pedestal 41. That is, at least a portion of backside surface 11b of seed crystal 11 is exposed to the atmosphere.

Furthermore, if adhesive 31 (see FIG. 5) is employed as means for connecting seed crystal 11 and pedestal 41, instead of fixture 33, in comparative example 2, adhesive 31 should be heat treated to bond them. As a result of the heat treatment, organic thin film 22 and adhesive 31 are thermally decomposed, and air bubbles are generated in organic thin film 22 and adhesive 31. Thus, air bubbles are also present in an interface between seed crystal 11 and organic thin film 22. Due to the air bubbles, there occurs a gap in the interface between organic thin film 22 and pedestal 41. That is, at least a portion of backside surface 11b of seed crystal 11 is exposed to the atmosphere.

As described above, in comparative examples 1 and 2, if there occurs a gap on backside surface 11b of seed crystal 11 (that is, if at least a portion of backside surface 11b of seed crystal 11 is exposed to the atmosphere), an element constituting backside surface 11b sublimes from the gap. If backside surface 11b of seed crystal 11 sublimes, heat conductivity of seed crystal 11 varies considerably, causing a reduction in the quality of crystal 13 grown on frontside surface 11a thereof.

In contrast, according to the present embodiment, film 12 is formed on seed crystal 11, and film 12 is at least one film selected from the group consisting of a hard carbon film, a diamond film, a Ta film, and a TaC film. The present inventor has found that a gap is less likely to occur in these films during formation and heating, and these films are less likely to be thermally decomposed when heat is applied thereto. Thus, occurrence of a gap between seed crystal 11 and film 12 is suppressed by forming film 12 on backside surface 11b of seed crystal 11. Further, even if heat is applied when crystal 13 is grown or when adhesive 31 is hardened (when seed crystal 11 is mounted on pedestal 41), since film 12 has a high melting point, decomposition of film 12 can be suppressed, and occurrence of a gap in film 12 is also suppressed. Thereby, a gap between backside surface 11b of seed crystal 11 and film 12 can be reduced. Thus, when crystal 13 is grown, backside surface 11b of seed crystal 11 is coated with film 12, which can suppress at least a portion of backside surface 11b of seed crystal 11 from being exposed to the atmosphere. Therefore, sublimation of backside surface 11b of seed crystal 11 can be suppressed. The present inventor has also found that crystallinity of grown crystal 13 is more influenced by a gap in an interface between seed crystal 11 and film 12, rather than a gap in an interface between adhesive 31 and pedestal 41. Hence, variations in heat conductivity of seed crystal 11 can be suppressed, and the temperature within seed crystal 11 can be uniform. Consequently, the quality of crystal 13 grown on seed crystal 11 can be improved.

In the present embodiment, it is particularly preferable that grown crystal 13 is a SiC crystal, the outermost layer of film 12 (layer to be mounted on pedestal 41) is a hard carbon film or a diamond film, the pedestal is graphite, and seed crystal 11 and pedestal 41 are connected using adhesive 31 including C. In this case, adhesive 31 is joined to film 12 including C, not to seed crystal 11. Thereby, bonding is performed among film 12 including C, pedestal 41, and adhesive 31 without directly depending on the material for seed crystal 11, and thus seed crystal 11 and pedestal 41 can be fixed more firmly.

Further, since the DLC film and the diamond film have high heat conductivity, the temperature within seed crystal 11 can be more uniform. Consequently, the quality of crystal 13 grown on seed crystal 11 can be significantly improved.

### EXAMPLES

In the present examples, an effect of forming at least one film selected from the group consisting of a hard carbon film, a diamond film, a tantalum film, and a tantalum carbide film on a backside surface of a seed crystal was examined.

### The Present Invention's Example 1

A manufacturing method for a crystal according to the present invention's example 1 was basically in accordance with the embodiment described above. Firstly, as shown in FIG. 3, a SiC substrate having a thickness of about 3 mm, a diameter of 60 mm, a polytype of 4H, and a plane orientation of (000-1) was prepared as seed crystal 11.

Next, a backside surface of seed crystal 11 was mechanically polished using diamond slurry having a particle size of about 15 μm.

Then, a DLC film as film 12 was formed on backside surface 11b of seed crystal 11. Specifically, the seed crystal was provided in a plasma polymerization apparatus. The plasma polymerization apparatus was a parallel plate type apparatus in which high-frequency applying electrodes, that is, a cathode electrode and an anode electrode, were placed in parallel. Thereafter, hydrocarbon gas was introduced from a gas inlet. Further, the pressure inside the apparatus was kept at 13 Pa, and high-frequency electric power with a frequency of 13.56 MHz was applied to generate plasma. On this occasion, the high-frequency electric power was one kilowatt. Thereby, a DLC film with a thickness of 1 μm was formed as film 12.

Subsequently, as shown in FIG. 4, film 12 and pedestal 41 were connected using adhesive 31. Specifically, firstly, graphite pedestal 41 having a mounting surface on which seed crystal 11 was to be mounted was prepared. Thereafter, the mounting surface was polished using diamond slurry. In addition, adhesive 31 including a phenol resin, phenol, ethyl alcohol, formaldehyde, water, and a solid carbon component was prepared. Film 12 and pedestal 41 were brought into contact with each other, with adhesive 31 interposed therebetween. Adhesive 31 was applied in an amount of about 25 mg/cm², with a thickness of about 40 μm. The contact was performed under conditions of a temperature of 100° C. and a pressure of 0.1 MPa. Thereafter, adhesive 31 was prebaked. As conditions therefor, heat treatment at 80° C. for four hours, heat treatment at 120° C. for four hours, and heat treatment at 200° C. for one hour were successively performed. Next, adhesive 31 was calcined. Heating therefor was performed at 1150° C. for one hour in a helium gas atmosphere at 80 kPa.

Then, as shown in FIG. 2, SiC powder as source material 51 was placed inside graphite source material holding unit 42. Then, pedestal 41 was mounted such that seed crystal 11 faced the inside of source material holding unit 42 and pedestal 41 functioned as a lid for source material holding unit 42.

Subsequently, a SiC crystal as crystal 13 was grown on seed crystal 11 by the sublimation method. The SiC crystal was grown at a temperature of 2400° C. and a pressure of 1.7 kPa, for 300 hours. Thereby, stacked film 10 (see FIG. 1) including film 12, seed crystal 11 formed on film 12, and crystal 13 formed on seed crystal 11 was manufactured.

Next, the obtained SiC crystal was sliced to obtain a SiC substrate. As a result of evaluating the SiC substrate, it had a void density of 0/cm² and a micropipe density of 1/cm².

The void density was measured by observing a cross section. The micropipe density was measured by soaking the SiC substrate in a KOH melt kept at 500° C. for 1 to 10 minutes, and performing a measurement on an etched surface thereof using a Nomarski differential interference microscope.

### The Present Invention's Example 2

In the present invention's example 2, a SiC crystal was manufactured basically as in the present invention's example 1. However, the present invention's example 2 was different from the present invention's example 1 in that a diamond film was used as film 12. Specifically, the diamond film was formed as described below.

Firstly, seed crystal 11 was provided in a microwave plasma CVD apparatus. Thereafter, 2 sccm methane, 90 sccm hydrogen, and 10 sccm nitrogen diluted to 1000 ppm in hydrogen were introduced into the apparatus. A diamond film was formed over 10 hours, with a temperature of a base material being set to 950° C. and a pressure being set to 13.3 kPa. Thereby, a polycrystalline diamond film with a thickness of 0.1 mm was formed.

When a SiC substrate obtained in the present invention's example 2 was evaluated as in the present invention's example 1, the SiC substrate had a void density of 0/cm² and a micropipe density of 1/cm².

### The Present Invention's Example 3

In the present invention's example 3, a SiC crystal was manufactured basically as in the present invention's example 1. However, the present invention's example 3 was different from the present invention's example 1 in that a Ta film was used as film 12. The Ta film was formed by the sputtering method.

When a SiC substrate obtained in the present invention's example 3 was evaluated as in the present invention's example 1, the SiC substrate had a void density of 0/cm² and a micropipe density of 1/cm².

### The Present Invention's Example 4

In the present invention's example 4, a SiC crystal was manufactured basically as in the present invention's example 1. However, the present invention's example 4 was different from the present invention's example 1 in that a TaC film was used as film 12. The TaC film was formed by the sputtering method.

When a SiC substrate obtained in the present invention's example 4 was evaluated as in the present invention's example 1, the SiC substrate had a void density of 0/cm² and a micropipe density of 1/cm².

### Comparative Example 1

In comparative example 1, a SiC crystal was manufactured basically as in the present invention's example 1. However, comparative example 1 was different from the present invention's example 1 in that film 12 was not formed, and seed crystal 11 and pedestal 41 were bonded using adhesive 31, as shown in FIG. 5.

In comparative example 1, seed crystal 11 fell from pedestal 41 with a probability of one third while the temperature was increasing to perform the sublimation method or while the crystal was growing. When a SiC substrate obtained in the case where the falling did not occur was evaluated as in the present invention's example 1, the SiC substrate had a void density of 10/cm² and a micropipe density of 50/cm². This is considered to be due to sublimation of backside surface 11b of seed crystal 11.

### Comparative Example 2

In comparative example 2, a SiC crystal was manufactured basically as in the present invention's example 1. However, comparative example 2 was different from the present invention's example 1 in that seed crystal 11 provided with 10 μm-thick organic thin film 22 instead of film 12 was fixed to pedestal 41 using mechanical fixture 33, as shown in FIG. 6.

When a SiC substrate obtained in comparative example 2 was evaluated as in the present invention's example 1, the SiC substrate had a void density of 120/cm² and a micropipe density of 300/cm². This is considered to be due to sublimation of backside surface 11b of seed crystal 11.

As described above, according to the present examples, it was able to be confirmed that a gap in the interface between seed crystal 11 and film 12 can be reduced and that the quality of the crystal can be improved, by forming at least one film selected from the group consisting of a hard carbon film, a diamond film, a tantalum film, and a tantalum carbide film on the backside surface of the seed crystal.

Although the embodiment and examples of the present invention have been described above, it is also originally intended to combine features of the embodiment and examples as appropriate. Although the present invention has been described and illustrated in detail, it is clearly understood that the same is by way of illustration and example only and is not to be taken by way of limitation, the scope of the present invention being interpreted by the terms of the appended claims.

What is claimed is:

1. A manufacturing method for a crystal, comprising the steps of:
preparing a seed crystal having a frontside surface and a backside surface opposite to said frontside surface;
forming at least one film selected from the group consisting of a hard carbon film, a diamond film, a tantalum film, and a tantalum carbide film on said backside surface of said seed crystal; and
growing the crystal on said frontside surface of said seed crystal.

2. The manufacturing method for the crystal according to claim 1, wherein, in said step of forming said film, a diamond-like carbon film is formed.

3. The manufacturing method for the crystal according to claim 1, wherein, in said step of forming said film, said hard carbon film is formed by plasma polymerization processing.

4. The manufacturing method for the crystal according to claim 1, wherein, in said step of forming said film, said diamond film as a polycrystal is formed.

5. The manufacturing method for the crystal according to claim 1, further comprising the step of polishing said backside surface of said seed crystal prior to said step of forming said film.

6. The manufacturing method for the crystal according to claim 1, further comprising the step of connecting said film and a pedestal using an adhesive.

7. The manufacturing method for the crystal according to claim 6, further comprising the step of polishing a region in said pedestal to be connected with said film prior to said step of connecting said film and the pedestal.

8. The manufacturing method for the crystal according to claim 1, wherein, in said step of growing, a silicon carbide crystal is grown.

9. A stacked film, comprising:
at least one film selected from the group consisting of a hard carbon film, a diamond film, a tantalum film, and a tantalum carbide film;
a seed crystal formed on said film; and
a crystal formed on said seed crystal.

10. A manufacturing apparatus for a crystal, comprising:
a source material holding unit for placing a source material therein; and
a pedestal holding a seed crystal at a position facing said source material placed inside said source material holding unit,
wherein said pedestal is connected with at least one film selected from the group consisting of a hard carbon film, a diamond film, a tantalum film, and a tantalum carbide film formed on a surface of said seed crystal to be connected with said pedestal.
